(19) United States
(12) Patent Application Publication
(10) Pub. No.: US 2006/0162661 A1
(43) Pub. Date: Jul. 27, 2006

(54) Mixing energized and non-energized gases for silicon nitride deposition

(75) Inventors: Kee Bum Jung, Gilroy, CA (US); Dale R. Du Bois, Los Gatos, CA (US); Lun Tsuei, Mountain View, CA (US); Lihua Li Huang, San Jose, CA (US); Martin Jay Seamons, San Jose, CA (US); Soovo Sen, Sunnyvale, CA (US); Reza Arghavani, Scotts Valley, CA (US); Michael Chiu Kwan, Sunnyvale, CA (US)

Correspondence Address: JANAH & ASSOCIATES, P.C., 650 DELANCEY STREET, SUITE 106, SAN FRANCISCO, CA, 94547, US

(73) Assignee: Applied Materials, Inc.

(21) Appl. No.: 11/040,712

(22) Filed: Jan. 22, 2005

(51) Int. Cl. H05H 1/24; C23C 16/00; H01L 21/306; C23F 1/00; B08B 6/00

(52) U.S. Cl. 118/723 ER; 427/569; 118/723 R; 118/715; 118/723 ME; 118/723 IR; 156/345.33; 134/1.1; 156/345.35

(57) ABSTRACT

A dual channel gas distributor can simultaneously distribute plasma species of an first process gas and a non-plasma second process gas into a process zone of a substrate processing chamber. The gas distributor has a localized plasma box with a first inlet to receive a first process gas, and opposing top and bottom plates that are capable of being electrically biased relative to one another to define a localized plasma zone in which a plasma of the first process gas can be formed. The top plate has a plurality of spaced apart gas spreading holes to spread the first process gas across the localized plasma zone, and the bottom plate has a plurality of first outlets to distribute plasma species of the plasma of the first process gas into the process zone. A plasma isolated gas feed has a second inlet to receive the second process gas and a plurality of second outlets to pass the second process gas into the process zone. A plasma isolator is between the second inlet and second outlets to prevent formation of a plasma of the second process gas in the plasma isolated gas feed.

### BACKGROUND

In the processing of a substrate in a chamber to fabricate circuits and displays, the substrate is typically exposed to energized gases that are capable of, for example, depositing or etching material on the substrate. For example, in a chemical vapor deposition (CVD) process, process gases are energized by for example, microwave or RF energy, to deposit a film on the substrate. The deposited films are further processed to create devices on the substrate such as, for example, metal-oxide-semiconductor field effect transistors (MOSFETs), which typically have a source region, a drain region, and a channel region therebetween. A gate electrode, above and separated from the channel by a gate dielectric, controls conduction between the source and drain. The performance of such MOSFETs can be improved, by for example, reducing supply voltage, gate dielectric thickness or channel length. However, these methods have diminishing returns as transistors shrink in size. For example, the advantages of reducing channel length, such as increasing the number of transistors per unit area and increasing the transistor saturation current, begin at very small channel lengths to be offset by carrier velocity saturation effects. Benefits from gate dielectric thickness reduction, such as decreased gate delay, are offset by increased gate leakage current and charge tunneling through the dielectric which may damage the transistor over time. Reducing the supply voltage allows for lower operating power, but reductions in the supply voltage are limited by the transistor threshold voltage.

Strain engineering, in which the atomic lattice of a deposited material is strained to affect the properties of the material, is used to further enhance transistor performance. Lattice strain can increase the carrier mobility of semiconductors, such as for example silicon, which increases the saturation current of transistors, thus increasing their performance. Strain can be introduced into materials formed on substrates in a number of ways. For example, localized strain can be induced in the channel region of the transistor by the deposition of component layers of the transistor which have internal compressive or tensile stress. In one version, silicon nitride layers are used as etch stop layers and as spacers during the formation of silicide layers on the gate electrode can be deposited to have a tensile stress which can induce a tensile stress in the channel region.

One common method to form stress-inducing layers on substrates is high density plasma chemical vapor deposition (HDP-CVD). However, HDP-CVD, and generally any process in which a plasma is created and maintained in the process zone of the substrate processing chamber, are typically compressive in nature, thus reducing the ability of the process to create a layer of material having a high internal tensile stress. For example, creating and maintaining a plasma in the process creates charged particles in the process zone that are accelerated by electric and magnetic fields present in the chamber which are used to create and maintain the plasma. The charged particles can impact and compress the silicon nitride layer as it is being formed, increasing the compressive stress internal to the layer, and thus reducing the ability of the process to create a silicon nitride layer having relatively high tensile stress.

Creating and maintaining a plasma in the process zone may also cause physical damage to or undesirably alter other layers on the substrate. For example, charged particles striking the substrate can travel along metalization layers of the transistor to the gate electrode, or in the deposition of the silicon nitride layer, may directly strike a polysilicon or silicide layer of the gate electrode. A build-up of charges on the gate electrode, known as gate charging, may cause charges to embed in the gate oxide layer below the electrode, which may degrade the transistor performance. For example, charge build-up in the gate oxide may lead to increased leakage current, which reduces the drive capacity of the transistor, or may cause permanent damage to the transistor.

Furthermore, CVD processes in which a plasma is created and maintained in the process zone may not be as conformal as thermally activated CVD processes. For example, electric and magnetic fields used to create and maintain the plasma in the process zone may influence the directionality of charged particles in the plasma, which can affect characteristics of the deposition, such as the ability to deposit a layer conformally to variously-oriented surfaces of the substrate. This may limit the ability of such CVD processes to deposit a silicon nitride layer that conforms to a varying surface topography of the transistor on the substrate.

Thus, there is a need for deposition of components of a transistor, such as a silicon nitride layer, having a relatively higher internal tensile stress. There is also a need for CVD deposition that does not undesirably damage components on the substrate. There is further a need for CVD deposition that is relatively more conformal to the underlying layers on the substrate.

### SUMMARY

A dual channel gas distributor can simultaneously distribute plasma species of a first process gas and a non-plasma second process gas into a process zone of a substrate processing chamber. The gas distributor has a localized plasma box with a first inlet to receive a first process gas, and opposing top and bottom plates that are capable of being electrically biased relative to one another to define a localized plasma zone in which a plasma of the first process gas can be formed. The top plate has a plurality of spaced apart gas spreading holes to spread the first process gas across the localized plasma zone, and the bottom plate has a plurality of first outlets to distribute plasma species of the plasma of the first process gas into the process zone. A plasma isolated gas feed has a second inlet to receive the second process gas and a plurality of second outlets to pass the second process gas into the process zone. A plasma isolator is between the second inlet and second outlets to prevent formation of a plasma of the second process gas in the plasma isolated gas distributor.

In a method of depositing a layer on a substrate in the processing chamber having a localized plasma zone directly above a process zone, the substrate is placed in the process zone. A localized plasma is formed and the plasma species are distributed into the process zone thorough a first gas pathway by introducing a first process gas into the localized plasma zone, forming a plasma from the first process gas in the localized plasma zone by maintaining an electric field across the localized plasma zone, and distributing the plasma species of the plasma of the first process gas across the process zone. Simultaneously with forming and distributing plasma species of the first process gas into the process zone, a non-energized second process gas is introduced into the process zone through a second gas pathway while suppressing formation of a plasma of the second process gas in the second gas pathway. Additionally, gases are also exhausted from the process zone. In one version, the first process gas comprises a nitrogen-containing gas, the second process gas comprises a silicon-containing gas, and silicon nitride is deposited on the substrate.

In another method of depositing a layer on a substrate in a substrate processing chamber, the substrate processing chamber comprising a process zone and a gas distributor to distribute first and second process gases to the process zone, the gas distributor comprising a localized plasma zone between a first and second electrode, the first process gas is introduced into the localized plasma zone through the first electrode, a voltage is applied between the first and second electrodes to couple energy to the first process gas, and the energized first process gas is introduced to the process zone through a first gas pathway. A second process gas is separately introduced to the process zone through a second gas pathway.

A method of cleaning a substrate processing chamber comprises introducing a first cleaning gas to the localized plasma zone through the first electrode, applying a voltage between the first and second electrodes to couple energy to the cleaning gas, and introducing the energized cleaning gas to the process zone through the second electrode, and exhausting the cleaning gas from the process zone. In one version, a second cleaning gas is also introduced into the process zone. In one version, the first cleaning gas comprises a fluorine containing gas. The first cleaning gas may also comprise argon. In one version, the second cleaning gas comprises NF₃.

Another embodiment of the dual channel gas distributor simultaneously distributes into a processing chamber a first process gas remotely energized in a remote gas energizing chamber that is distal from the processing chamber and a non-energized second process gas. The gas distributor has a remotely energized gas channel comprising a first inlet to receive the remotely energized first process gas and a plurality of first outlets to release the remotely energized first process gas into the processing chamber. The gas distributor also has a non-energized gas channel comprising a second inlet to receive a non-energized second process gas and a plurality of second outlets to introduce the received non-energized second process gas into the processing chamber, the second outlets being interspersed and on substantially the same plane with the first outlets. In one version, the gas distributor comprises a cover plate having radial channels that form a plurality of third outlets at the perimeter of the cover plate. In one version, each first outlet has a size d₁, each second outlet has a size d₂, each third outlet has a size d₃, the ratio d₁:d₂ has a value of from about 5:1 to about 20:1, and the ratio d₃:d₂ has a value of from about 10:1 to about 40:1.

In another method of depositing a layer on a substrate in a processing chamber, the substrate is placed in the process zone. A remotely energized first process gas is formed in a remotely energized gas zone and introduced into the process zone though a first gas pathway. Simultaneously with introducing the remotely energized first process to the process zone, a second non-energized process gas is separately introduced into the process zone through a second gas pathway. In one version, the first process gas is remotely energized by coupling microwave energy to the first process gas. In another version, the first process gas is remotely energized by inductively coupling RF energy to the first process gas.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a schematic view of an embodiment of a substrate processing chamber;

FIGS. 2a-c are schematic views of three different embodiments of a first gas supply comprising a remote plasma system;

FIG. 3 is a sectional view of an embodiment of a dual channel gas distributor;

FIG. 4 is an exploded perspective view of the dual channel gas distributor shown in FIG. 3;

FIG. 5 is a partial sectional perspective view of a faceplate of the dual channel gas distributor shown in FIGS. 3 and 4;

FIG. 6 is a perspective view of a plasma isolator of the dual channel gas distributor shown in FIGS. 3 and 4;

FIG. 7 is a partial sectional view of a gas inlet of the faceplate shown in FIG. 5;

FIG. 8 is a sectional view of another embodiment of the dual channel gas distributor;

FIG. 9 is a perspective view of a cover plate of the dual channel gas distributor show in FIG. 8;

FIG. 10 is a cross-sectional top view of the cover plate shown in FIG. 9;

FIG. 11 is a perspective view of a spreader plate of the dual channel gas distributor shown in FIG. 8;

FIG. 12 is a sectional view of yet another embodiment of the dual channel gas distributor;

FIG. 13 is a perspective view of a top spreader plate of the dual channel gas distributor shown in FIG. 12;

FIG. 14 is a perspective view of a bottom spreader plate of the dual channel gas distributor shown in FIG. 12; and

FIG. 15 is a simplified cross-sectional view of a transistor having a silicon nitride layer.

### DESCRIPTION

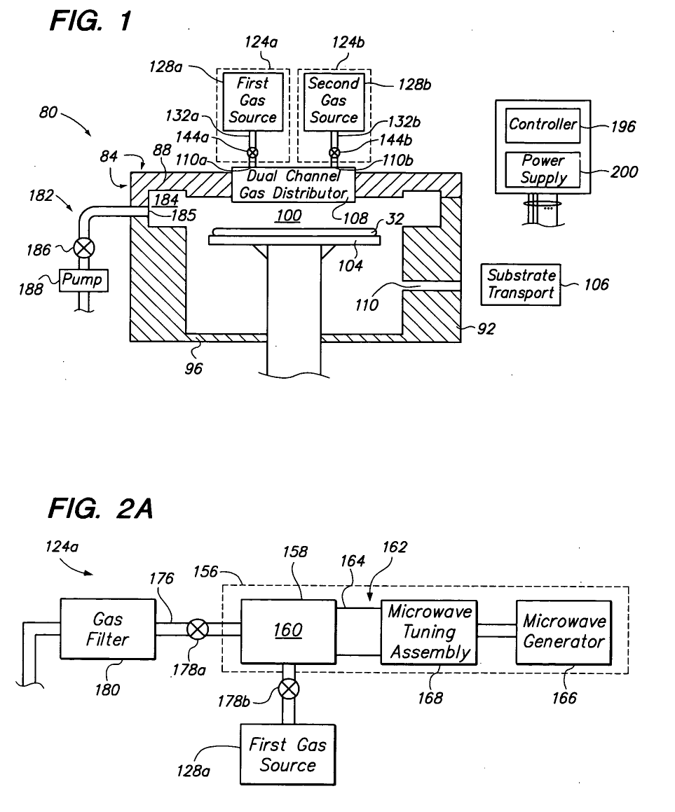

A substrate processing chamber 80 can be used for chemical vapor deposition (CVD) of a layer on a substrate 32. An embodiment of the chamber is schematically illustrated in FIG. 1 and comprises enclosure walls 84, which include a ceiling 88, sidewalls 92, and a bottom wall 96, that enclose a process zone 100. The chamber 80 may also comprise a liner (not shown) that lines at least a portion of the enclosure walls 84 about the process zone 100. The substrate 32 is loaded on a substrate support 104 by a substrate transport 106 such as, for example, a robot arm, through an inlet port 110. The substrate support 104 and substrate 32 can be moved between a lower position, where the substrate 32 can be loaded or unloaded, for example, and a processing position closely adjacent to a dual channel gas distributor 108. In one version, the substrate support 104 is heated and includes an electrically resistive heating element (not shown). The substrate support 104 typically comprises a ceramic material which protects the heating element from potentially corrosive chamber environments and allows the support 104 to attain temperatures up to about 800° C. The substrate support 104 may also comprise an electrode (not shown) to electrostatically clamp the substrate 32 to the support 104 or to energize gases in the chamber 80. The substrate support 104 may also comprise one or more rings (not shown) that at least partially surround a periphery of the substrate 32 to secure the substrate 32 on the support 104, or to otherwise aid in processing the substrate 32 by, for example, focusing energetic plasma species onto the substrate 32.

A dual channel gas distributor 108 is located directly above the process zone 100 for dispersing gases to the process zone 100, and distributes first and second process gases uniformly and radially spread across the substrate surface. The gas distributor 108 is capable of separately delivering two independent streams of first and second process gases to the process zone 100 without fluidly coupling or mixing the gas streams prior to their introduction into the process zone 100. Thus, the dual channel gas distributor 108 comprises at least first and second gas pathways that are separate pathways. The substrate processing chamber 80 also comprises first and second gas supplies 124a,b to deliver the first and second process gases to the gas distributor 108. In one version, the gas supplies 124a,b each comprise a gas source 128, one or more gas conduits 132, and one or more gas valves 144. For example, in one version, the first gas supply 124a comprises a first gas conduit 132a and a first gas valve 144a to deliver a first process gas from the gas source 128a to a first inlet 110a of the dual channel gas distributor 108, and the second gas supply 124b comprises a second gas conduit 132b and a second gas valve 144b to deliver a second process gas from the second gas source 128b to a second inlet 110b of the dual channel gas distributor 108.

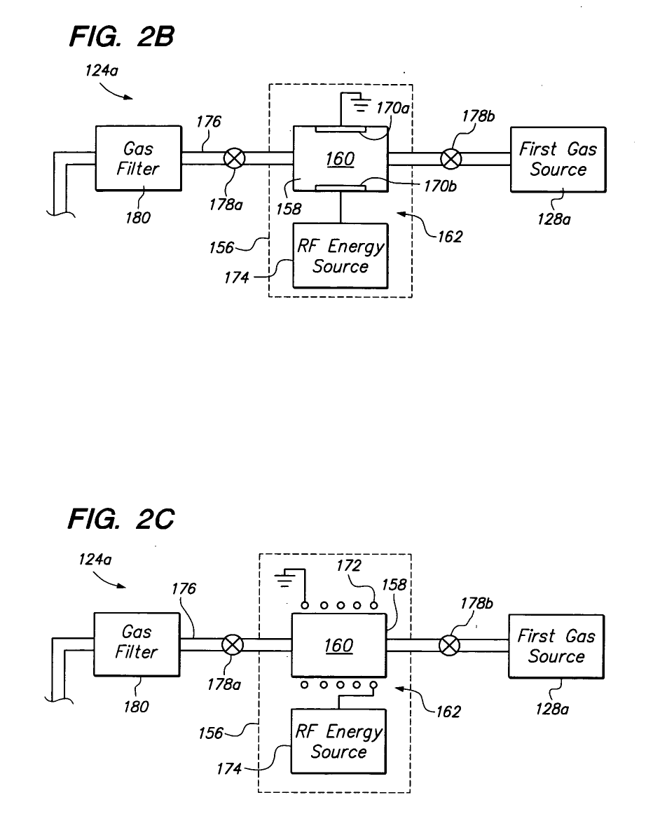

In another version, as illustrated in FIGS. 2a-c, the first gas supply 124a instead comprises a remote plasma system 156 to energize the first process gas remotely from the processing chamber 80. The remote plasma system 156 comprises a remote plasma chamber 158, such as a quartz tube or a torroidally or cylindrically shaped chamber, which is supplied with a first process gas from the first gas source 128a. The remote chamber 158 is upstream from the processing chamber 80 and comprises a remote plasma zone 160 in which a first process gas may be energized using a remote gas energizer 162 that couples electromagnetic energy, such as microwave or RF energy, to the first process gas. When electromagnetic energy is applied to the first process gas, it may dissociate to form energized or plasma species that react more readily with the second process gas in the processing chamber 80. The first process gas supplied to the remote chamber 158 may comprise, for example, a nitrogen-containing gas such as NH₃, which may dissociate under the application of electromagnetic energy to form NH₂, NH, N, H₂, H, ionized species of these, or a combination thereof. The dissociated or ionized species react more readily with the second process gas.

In one embodiment, as schematically illustrated in FIG. 2a, the remote gas energizer 162 comprises a microwave waveguide 164 that transmits microwaves that are generated by a microwave generator 166 and tuned by a microwave tuning assembly 168. Instead of or in addition to using microwaves, the first process gas may also be activated by RF energy that is applied to the process gas by inductive or capacitive coupling. For example, as illustrated in FIG. 2b, a suitable RF gas energizer 162 comprises a pair of electrodes 170a,b positioned within the remote chamber 158 to provide a capacitively coupled field in the chamber 158. As another example, as illustrated in FIG. 2c, the RF gas energizer 162 may comprise an inductor antenna 172 comprising a coil wrapped around the remote chamber 158. In each of the embodiments, the RF gas energizer 162 is powered by a suitable RF energy source 174.

In one version, the remote chamber 158 is located a relatively short distance upstream from the processing chamber 80. This allows the remote plasma system 156 to provide a higher concentration of dissociated species of the first process gas to the processing chamber 80 for deposition on the substrate 32. Typically, some of the dissociated species may recombine during travel from the remote chamber 158 to the processing chamber 80. However, a shorter upstream distance may reduce such recombination effects. Thus, in one version, the remote chamber 158 is located a distance of less than about 50 cm upstream of the processing chamber 80, or may even be located a distance of less than about 1 cm upstream. The upstream distance is determined by the composition of the first process gas, the energy applied by the remote gas energizer 162 in the remote chamber 158, and the nature of the CVD reaction taking place in the processing chamber 80. Thus, other distances may be more appropriate for different chamber configurations, gas compositions, or CVD reactions.

The first gas supply 124a comprising the remote plasma system 156 delivers the energized first process gas to the processing chamber 80, and in one version, a conduit 176 connects the remote chamber 158 to the processing chamber 80, with optionally, one or more gas valves 178a,b to control the flow of the energized first process gas through the conduit. The conduit 176 and gas valves 178a,b are adapted as necessary to withstand erosion by the energetic plasma species. Other components of the remote plasma system 156, for example the remote plasma chamber 158, also comprise materials that are resistant to attack by the plasma. Optionally, a filter 180 may be positioned in the conduit 176 to remove any particulate matter that may be formed while energizing the first process gas. In one embodiment, the filter 180 is made of a porous ceramic material, however, other materials can also be used, such as for example, Teflon (™) DuPont de Nemours, Inc., polyimide, inactivated carbon or sulphur. Examples of the remote plasma system 156 commercially available are the Xstream Remote Plasma Source from Advanced Energy Industries, Inc., in Fort Collins, Colorado, U.S.A., the ASTRON Reactive Gas Generators from MKS Instruments Inc., in Wilmington, Massachusetts, U.S.A., and the ASTeX Microwave Plasma Sources, also from MKS Instruments, Inc.

The chamber 80 also comprises a gas exhaust 182 to remove spent process gases and byproducts from the chamber 80. In one version, the gas exhaust 182 includes a pumping channel 184 that receives spent process gas from the process zone 100, an exhaust port 185, and a throttle valve 186 and one or more exhaust pumps 188 to control the pressure of process gas in the chamber 80. The chamber 80 may also comprise an inlet port or tube (not shown) through the bottom wall 96 of the chamber 80 to deliver a purging gas into the chamber 80. The purging gas typically flows upward from the inlet port past the substrate support 104 and to an annular pumping channel. The flow of purging gas may be used to protect surfaces of the substrate support 104 and other chamber components from undesired deposition during the processing of the substrate 32. The purging gas may also be used to affect the flow of process gases in a desirable manner.

The chamber 80 also comprises a controller 196 that controls activities and operating parameters of the chamber 80. The controller 196 may comprise, for example, a processor and memory. The processor executes chamber control software, such as a computer program stored in the memory. The memory may be a hard disk drive, read-only memory, flash memory or other types of memory. The controller 196 may also comprise other components, such as a floppy disk drive and a card rack. The card rack may contain a single-board computer, analog and digital input/output boards, interface boards and stepper motor controller boards. The chamber control software includes sets of instructions that dictate the timing, mixture of gases, chamber pressure, chamber temperature, microwave power levels, RF power levels, susceptor position, and other parameters of a particular process. The chamber 80 also comprises a power supply 200 to deliver power to various chamber components such as, for example, a substrate support 104, the gas supplies 124, the controller 196, and other components.

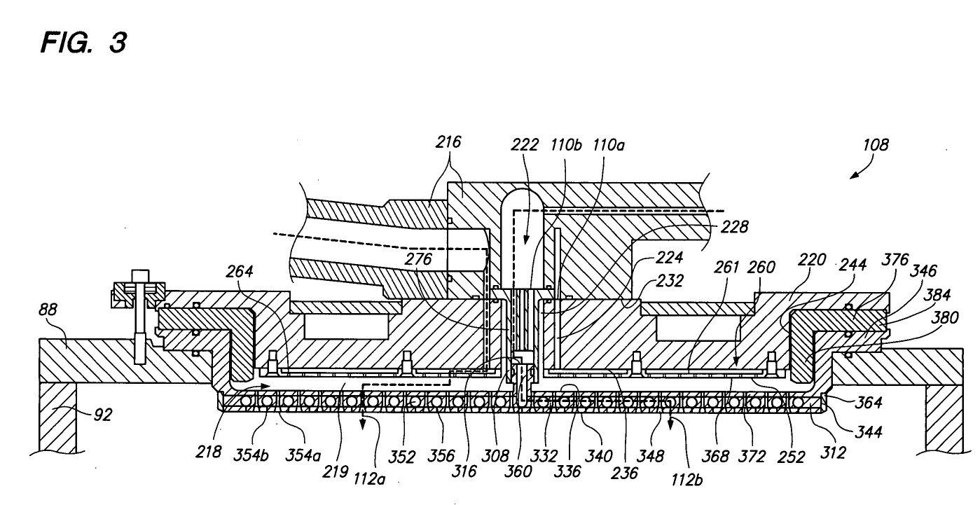

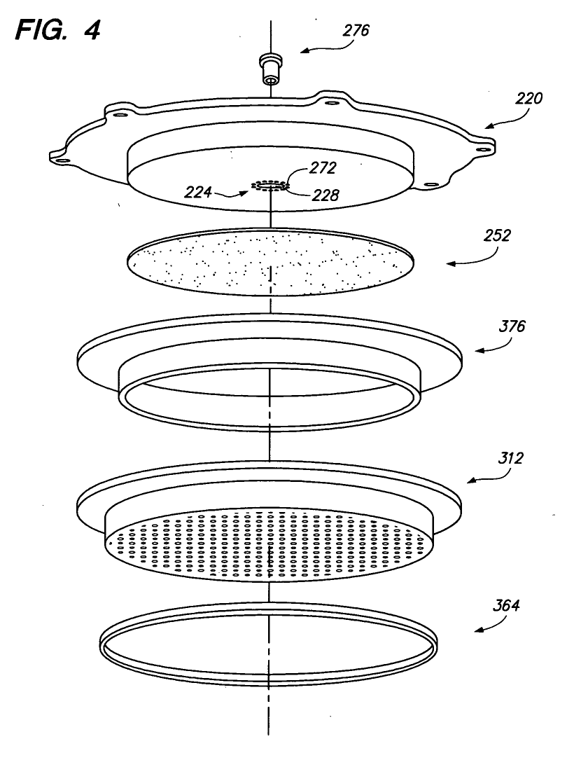

One embodiment of the dual channel gas distributor 108, illustrated in the cross-sectional view of FIG. 3 and the exploded perspective view of FIG. 4, is capable of simultaneously distributing plasma species of the first process gas and the non-plasma second process gas into the process zone 100 of the processing chamber 80. The gas distributor 108 receives the non-energized first and second process gases from the first and second gas supplies 124a,b through a gas manifold 216 connected to the gas distributor 108. The gas manifold 216 delivers the process gases to the gas distributor 108 through two separate channels and may comprise at least a portion of the gas conduits 132a,b and gas valves 144a,b of the gas supplies 124a,b. In a preferred version, this embodiment of the dual channel gas distributor 108 is used with the embodiment of the first gas supply 124a shown in FIG. 1, however it can also be used with the embodiments of the first gas supply 124a as shown in FIGS. 2a-c.

The embodiment of the gas distributor 108 shown in FIGS. 3 and 4 comprises a localized plasma box 218 to generate a plasma from the first process gas and distribute the plasma to the process zone 100. The plasma box 218 comprises the first inlet 110a of the gas distributor 108 to receive the first process gas from the first gas supply 124a. The first inlet 10a to the plasma box 218 of the gas distributor 108 can be formed in a cover plate 220 which has a top surface 232 that is connected to the gas manifold 216. The cover plate 220 has a first conduit 224 that, in one version, originates at the first inlet 110a at the top surface 232 of the cover plate 220 and terminates at a bottom surface 236 of the cover plate 220. The first conduit 224 may comprise several geometries and in one version comprises an annular gas passage. For example, the annular passage may comprise a plurality of cylindrical or otherwise-shaped holes 272 collectively arranged in an annular configuration.

The localized plasma box 218 comprises opposing top and bottom plates 252, 312 that are capable of being electrically biased relative to one another to define a localized plasma zone 219 in which a plasma from the first process gas can be formed. In one version, the top plate 252 of the localized plasma box 218 is a spreader plate 252 which has a body 256 spaced apart from the cover plate 220 by a separation distance to form a spreading box 260 having a gas spreading zone 261 between the cover plate 220 and the top plate 252. The spreading box 260 receives the flow of the first process gas from the first conduit 224 and distributes the first process gas to the localized plasma zone 219. The spreading box 260 increases the uniformity and spread of the first process gas across the width of the gas distributor 108 as it passes into the localized plasma box 218. The spreader plate 252 has a plurality of spaced apart gas spreading holes 264 to spread the first process gas across the localized plasma zone 219, and the plurality of holes 264 are arranged in a pattern that provide the uniform distribution of the first process gas to the localized plasma zone 219. For example, the pattern of holes 264 in the spreader plate 252 may be radially symmetric or asymmetric, as well as have characteristics that are concentric or non-concentric to the center of the spreader plate 252.

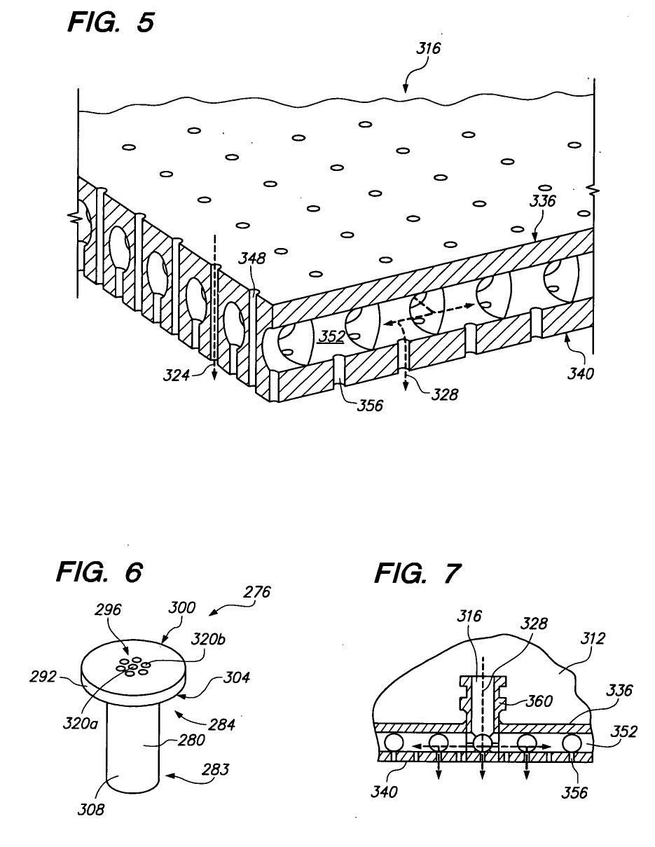

The bottom plate 312 of the localized plasma box 218 comprises a plurality of first outlets 354a to distribute plasma species of the plasma of the first process gas into the process zone 100. In one version, the bottom plate 312 of the localized plasma box 218 is a dual channel faceplate 312, a partial cross-sectional perspective view of an embodiment of which is illustrated in FIG. 5. The dual channel faceplate 312 comprises separate first and second gas passages 324, 328 to distribute the first and second process gases. The faceplate 312 is spaced apart from the spreader plate 252 by a separation distance to create the localized plasma zone 219 between the spreader plate 252 and the faceplate 312 into which the first process gas is distributed by the holes 264 in the spreader plate 252. The faceplate 312 comprises a body 332 having a top surface 336 facing the localized plasma zone 219, a bottom surface 340 facing the process zone 100, and a peripheral annular sidewall 344. The faceplate 312 also comprises an outer flange 346 to connect the faceplate 312 to the enclosure walls 84 of the substrate processing chamber 80. The first gas passage 324 of the faceplate 312 comprises a set of vertical channels 348 extending from the top surface 336 of the faceplate 312 to the bottom surface 340 of the faceplate 312 to form the plurality of first outlets 354a of the localized plasma box to the process zone 100. The vertical channels 348 are arranged in a symmetric pattern about the center of the faceplate 312 and are sized to provide suitable flow characteristics of plasma species from the localized plasma zone 219 to the process zone 100.

The cover plate 220 and the top plate 252 can together or individually form a first electrode 368 of the localized plasma box, and the faceplate 312 forms the second electrode 372. The top plate 252 is connected and electrically coupled to the cover plate 220 at connection points. The cover plate 220, top plate 252, and faceplate 312 comprise an electrically conductive material such as, for example, aluminum, aluminum alloy, stainless steel, nickel, an electrically conductive aluminum nitride, or a combination thereof. In one version, the cover plate 220 comprises a first electrical connector (not shown) to receive a first voltage from the power supply 200, and the faceplate 312 comprises a second electrical connector (not shown) to receive a second voltage from a power supply 200. In one version, the second electrode 372 is electrically grounded, however, the first and second electrodes 368, 372 are both capable of receiving voltage signals from the power supply 200 to energize the first process gas in the localized plasma zone 219. The first and second electrodes 368, 372 are capable of coupling energy into the localized plasma box 218 by being electrically biased relative to one another to thus maintain an electric field in the localized plasma box 218 which energizes the first process gas to form a plasma from the first process gas.

The embodiment of the dual channel gas distributor 108 shown in FIGS. 3 and 5 also comprises a plasma isolated gas feed 222 to distribute the second process gas into the process zone 100. The plasma isolated gas feed 222 comprises the second inlet 110b of the gas distributor 108 to receive the second process gas from the gas manifold 216, and a plasma isolator 276 between the second inlet 110b and a plurality of second outlets 354b. In one version, the plasma isolator 276 sits in a second conduit 228 which is a centrally located passage in the cover plate 220. For example, the annular first conduit 224 may be concentric to the central second conduit 228. In one version, the second inlet 110b coincides with beginning of the second conduit 228 and the plasma isolator 276.

An embodiment of the plasma isolator 276 is illustrated in FIG. 6. The plasma isolator 276 isolates the second process gas from voltages and electromagnetic fields about the cover plate 220 and localized plasma box 218. The plasma isolator 276 comprises an insulating material. In one version, the plasma isolator 276 may comprise a ceramic such as, for example, aluminum oxide (alumina) or quartz. In another version, the plasma isolator 276 may comprise a polymer such as, for example, polytetrafluoroethylene (PTFE) or polyetheretherketone (PEEK). PTFE is available, for example, as Teflon™ from DuPont in Wilmington, Delaware. The plasma isolator 276 may also comprise a combination of the above-listed materials. In the embodiment shown in FIG. 6, the plasma isolator 276 comprises a cylindrical body 280 having first and second ends 284, 288 and a plurality of holes 320 from the first end 284 to the second end 288. In this version, the intersection of the plurality of holes 320 with the first end 284 of the cylindrical body 280 comprises the second inlet 110b of the plasma isolated gas feed 222. At the first end 284 of the cylindrical body 280 is an annular flange 292 having a first and second surface 300, 304, the first surface 300 coupling to the gas manifold 216, the second surface 304 coupling to the cover plate 220. At the second end 288 of the cylindrical body 280 is an annular protrusion 308 adapted to couple the plasma isolator 276 to a gas inlet 316 of the faceplate 312.

The plurality of holes 320 passing from the first end 284 to the second end 288 of the plasma isolator 276 prevent the passage of a plasma from the process zone 100 or the localized plasma box 218 back through the plasma isolated gas feed 222 to the gas manifold 216. It is important to prevent plasma from passing back through the plasma isolated gas feed 222 to the gas manifold 216 because portions of the gas manifold 216 may not be capable of accommodating an energized gas or plasma, and may experience corrosion, etching, or deposition upon contact with a plasma. In one version, the plurality of holes 320 are cylindrical holes 320 which are arranged in a pattern. For example, as illustrated in FIG. 6, the plurality of holes 320 may comprise a central hole 320a and six peripheral holes 320b arranged hexagonally about the central hole 320a. The cylindrical holes 320 are sized sufficiently small to prevent the passage of a plasma through the plasma isolator 276 and sufficiently large to be capable of a suitable gas flow. For example, in one version, the cylindrical holes 320 have a diameter of from about 2 mm to about 4 mm. The plasma-quenching capability of the plasma isolator 276 is also derived from the insulating material of which it comprises, which prevents or reduces electromagnetic radiation or other energy from coupling to the second process gas in the plasma isolator 276.

The plasma isolated gas feed 222 also comprises a plurality of second outlets 354b to pass the second process gas into the process zone 110. In one version, the plurality of second outlets 354b of the plasma isolated gas feed 222 are fed from an interlinked network of channels 352 in the faceplate. In this version, the faceplate has a second gas passage 328 that is coupled to the plasma isolator 276 to receive the second process gas from the plasma isolator 276 and distribute it to the process zone 100. The second gas passage 328 comprises the set of interlinked channels 352 extending through the faceplate body 332 from the peripheral sidewall 344. This set of interlinked horizontal channels 352 feeds the second outlets 354b of the plasma isolated gas feed 222, which in this version comprise the intersection of a set of holes 356 extending from the horizontal channels 352 to the process zone 100 with the bottom surface 340 of the faceplate body 332.

The set of interlinked horizontal channels 352 comprises an inlet 316 through the top surface 336 of the faceplate body 332. The inlet 316 is coupled to the plasma isolator 276 and distributes the second process gas from the plasma isolator 276 to the interlinked channels 352. An embodiment of the gas inlet 316 is illustrated in FIG. 7, and comprises by a nozzle 360 protruding from the first surface 336 of the faceplate body 332 that couples to the annular protrusion 308 of the plasma isolator 276. For example, in one version, the nozzle 360 fits inside the annular protrusion 308 of the plasma isolator 276 and may have an o-ring (not shown) to seal the connection between the nozzle 360 and the plasma isolator 276.

The body 332 of the faceplate 312 is monolithic, i.e., machined or otherwise fabricated as a single piece of material, where the size and spacing of the holes and channels may be varied according to the particular application, so that uniform delivery into the processing chamber 80 is achieved. Manufacturing the faceplate 312 as a single piece of material avoids problems encountered with aligning separate plates and preventing leakage of gases between plates and into separate channels. The horizontal channels 352 may be formed by machining, ie., drilling through the sidewall 344, in a plane generally parallel with the top surface 336 and bottom surface 340 of the faceplate 312. The faceplate 312 also comprises an annular ring 364 about the peripheral sidewall 344 of the faceplate body 332 to hermetically seal the endpoints of the horizontal channels 352 of the faceplate 312. In one version, the annular ring 364 is welded to the peripheral sidewall 344 of the faceplate 312. However, other methods to provide the hermetic seal of the annular ring 364 to the peripheral sidewall 344 are possible, including brazing, threading, electron beam welding, or placing an o-ring (not shown) between the annular ring 364 and peripheral sidewall 344.

The first and second outlets 354a,b of the dual channel gas distributor 108 are interspersed with each other and are on substantially the same plane. This allows the dual channel gas distributor 108 to distribute the energized first process gas and the second process gas to the process zone 100 in a manner optimized for the CVD reaction in the process zone 100. The energized first process gas and the non-energized second process gas are mixed uniformly to avoid undesirable effects such as gas phase nucleation of the process gases to create unwanted particles in the process zone before the reactants absorb on the surface of the deposited film. To assist in avoiding gas phase nucleation, the first and second outlets 354a,b of the gas distributor 108 are uniformly interspersed with each other. For example, in the version of the faceplate 312 shown in FIG. 5, the first and second outlets 354a,b are arranged in overlapping square grids. For example, the first and second outlets 354a,b are each arranged into square grids, which are then offset from each other, i.e. the square grid of first outlets 354a are offset relative to the square grid of second outlets 354b. This configuration provides for a uniform mixing of the first and second process gases in the process zone 100. In one version, each square grid of outlets has a periodic separation distance between outlets. For example, in one version, the plurality of first outlets 354a and the plurality of second outlets 354b may each be arranged in a square grid having a periodic separation distance of from about 5 mm to about 15 mm, or even from about 8 mm to about 13 mm.

The plurality of first and second outlets 354a,b may also be sized relative to one another to optimize the delivery of plasma species of the energized first process gas into the process zone 100 and to optimize the uniformity of the mixing of the first and second process gasses in the process zone 100. The first outlets 354a have a size d₁ and the second outlets 354b have a size d₂. For example, the first and second outlets 354a,b may be circular and thus the sizes d₁ and d₂ are equal to the diameters of the circular outlets. In one version, d₁ and d₂ have values of from about 0.1 mm to about 3 mm, and in another version may even have values of from about 0.1 mm to about 0.5 mm.

The gas distributor 108 also comprises an electrical isolator 376 between the periphery 244 of the cover plate 220 and the faceplate 312. The electrical isolator 376 electrically isolates the first electrode 368 of the gas distributor 108 from the second electrode 372 of the gas distributor 108. An embodiment of the electrical isolator 376 comprises a ring having a vertical wall 380 and a horizontal flange 384. Both the vertical wall 380 and the horizontal flange 384 are positioned between surfaces of the cover plate 220 and the faceplate 312. The cross-sectional thickness of both the vertical wall 380 and the horizontal flange 384 are selected to be great enough to electrically isolate the gas box 220 from the faceplate 312. For example, in one version, this thickness is selected to be from about 7.5 mm to about 20 mm, or even from about 12 mm to about 16 mm. The electrical isolator 376 comprises an insulating material. In one version, the electrical isolator 376 may comprise a ceramic such as, for example, aluminum oxide (alumina) or quartz. In another version, the electrical isolator 376 may also comprise a polymer such as, for example, polytetrafluoroethylene (PTFE) or polyetheretherketone (PEEK). PTFE is available, for example, as Teflon™ from DuPont in Wilmington, Delaware. The electrical isolator 376 may also comprise a combination of the above-listed materials.

A method of forming a layer on the substrate 32 in the chamber 80 is suitable for use with the embodiment of the dual channel gas distributor 108 illustrated in FIGS. 3 and 4. In the method, the substrate 32 is placed in the process zone 100 by the substrate transport 106 through the inlet port 110. The support 104 with the substrate 32 is raised to a processing position closer to the gas distributor 108. The chamber 80 may comprise a sensor (not shown) to aid in accurately positioning the substrate support 104 relative to the gas distributor 108. Upon completion of processing of the substrate 32, support lift pins (not shown) are activated to lift the substrate 32 off the support 104, allowing the substrate transport 106 to remove the substrate 32 from the processing chamber 80.

The first process gas is energized in the localized plasma zone 219 of the plasma box 218 of the dual channel gas distributor 108 prior to its introduction into the process zone 100 by the gas distributor 108. The first process gas can be energized by coupling electromagnetic energy, for example RF energy, into the non-energized first process gas to form a plasma from the first process gas. Plasma species of the plasma formed from the first process gas are introduced into the process zone 100 through the first outlets 354a of the gas distributor 108. Generally, the first process gas follows the first gas flow pathway 112a through the gas distributor 108, which is separate from the second gas flow pathway 112b traveled by the second process gas.

In one version, the first process gas is introduced into the localized plasma zone 204 through the first electrode 368 of the gas distributor 108. For example, the first process gas can be introduced into the localized plasma zone 204 through the holes 264 in the top plate 252. To energize the first process gas, a voltage is applied between the first and second electrodes 368, 372 to couple energy to the first process gas in the localized plasma zone 204. For example, energy can be capacitively coupled into the localized plasma zone 204 by applying a first voltage to the first electrode 368 and a second voltage to the second electrode 372. The second electrode 372 may also be grounded such that the first voltage may be applied between the first and second electrodes 368, 372. The voltage applied to the first electrode 368 can, for example, generate RF energy at a power level of from about 30 W to about 1000 W, and at a frequency of from about 350 kHz to about 60 MHz. In this version of the method, the plasma formed from the first process gas is introduced to the process zone 100 through the second electrode 372. For example, the energized first process gas can be introduced into the process zone 100 through first outlets 354a comprising the intersection of the vertical channels 348 of the faceplate 312 with the bottom surface 340 of the faceplate 312.

The first and second process gases are separately introduced into the process zone 100 by the dual channel gas distributor 108. The first and second process gasses are kept fluidly separate until they enter the process zone 100 to avoid reaction of the process gases before they enter the process zone 100. The first and second process gases can typically react immediately upon mixing causing gas phase nucleation and particulate formation or undesirable deposition in upstream portions of the chamber 80, such as, for example, the gas conduits 132, gas valves 144, and gas distributor 108. Deposition of process residues in these areas outside the process zone 100 is detrimental to the operation and reliability of the chamber 80 and may result in decreased substrate yields and increased chamber maintenance and cleaning.

The second process gas is introduced into the process zone 100 through the second gas flow pathway 112b of the gas distributor 108. The second process gas is not energized before it is introduced into the process zone 100. The second process gas is received by the second inlet 110b of the gas distributor and introduced into the process zone 100 through the second gas outlets 354b comprising the intersection of the holes 356, which couple the interlinked horizontal channels 352 to the process zone, 100 with the bottom surface 340 of the faceplate 312.

Process gases are removed from the process zone 100 to maintain a selected pressure in the process zone 100. Process gases in the process zone 100 may comprise the first and second process gases, as well as byproducts of the CVD reaction occurring in the process zone 100. The process gases are removed from the process zone 100 by the gas exhaust 160, which may comprise one or more pumps 188 specifically selected to effectively remove certain process gases. For example, the exhaust pump 188 may comprise a turbomolecular pump, a cryogenic pump, or a roughing pump. Furthermore, the exhaust may comprise a pump 188 that combines the functionality of pumps, such as a cryo-turbo pump that combines the functionality of a cryogenic pump and a turbomolecular pump. The exhaust pump 188 may also comprise other types of pumps.

Process gases are removed from the process zone 100 at a rate selected to create a pressure within the process zone 100 optimized for the creation of a layer on the substrate 32. Relatively lower pressures are advantageous for the formation of the layer on the substrate 32 because they create a longer mean free path of travel for gaseous species in the process zone 100. This is good because it helps increase the conformality of the deposited layer.

The embodiment of the dual channel gas distributor 108 illustrated in FIGS. 3 and 4 is also suitable to implement a method of cleaning the substrate processing chamber 80. In this method, a first cleaning gas is introduced to the localized plasma zone 219 through the first electrode 368. A voltage is applied between the first and second electrodes 368, 372 to couple energy to the cleaning gas, and the energized cleaning gas is introduced to the process zone 100 through the second electrode 372. In one version of this method, a second cleaning gas is also introduced to the process zone 100. For example, the second cleaning gas can be introduced through the second gas flow pathway 112b comprising the plasma isolated gas feed 222. In one version of the cleaning method, the first cleaning gas comprises a fluorine-containing gas. The first cleaning gas may also comprise argon. In one version of the cleaning method, the second cleaning gas comprises NF₃. Gases are also exhausted from the process zone 100 to maintain a selected pressure in the process zone 100. For example, the pressure in the process zone 100 can be maintained at from about 2 Torr to about 10 Torr during the cleaning process.

Another embodiment of the dual channel gas distributor 108 comprising two fluidly separate gas flow pathways 112 is illustrated in the cross-sectional view of FIG. 8. This embodiment of the gas distributor 108 is capable of simultaneously delivering to the process zone 100 a first process gas which is remotely energized in the remote gas energizing zone 160 of the remote plasma system 156 and a non-energized second process gas. In the version shown in FIG. 8, the gas distributor 108 receives the energized first process gas and the non-energized second process gas from the gas manifold 216 connected to the gas distributor 108. The gas distributor 108 comprises the first gas flow pathway 112a for the energized first process gas and the second gas flow pathway 112b for the non-energized second process gas.

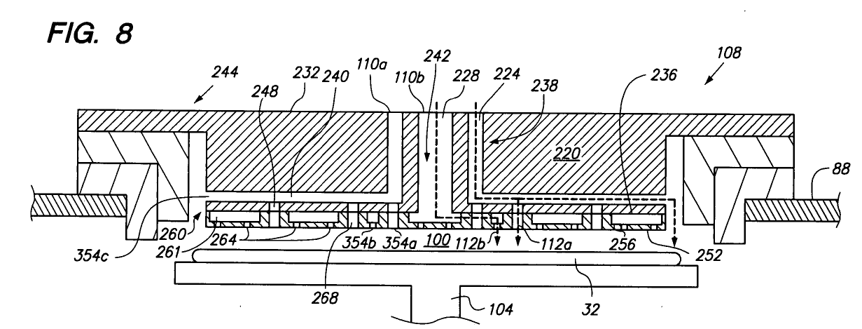

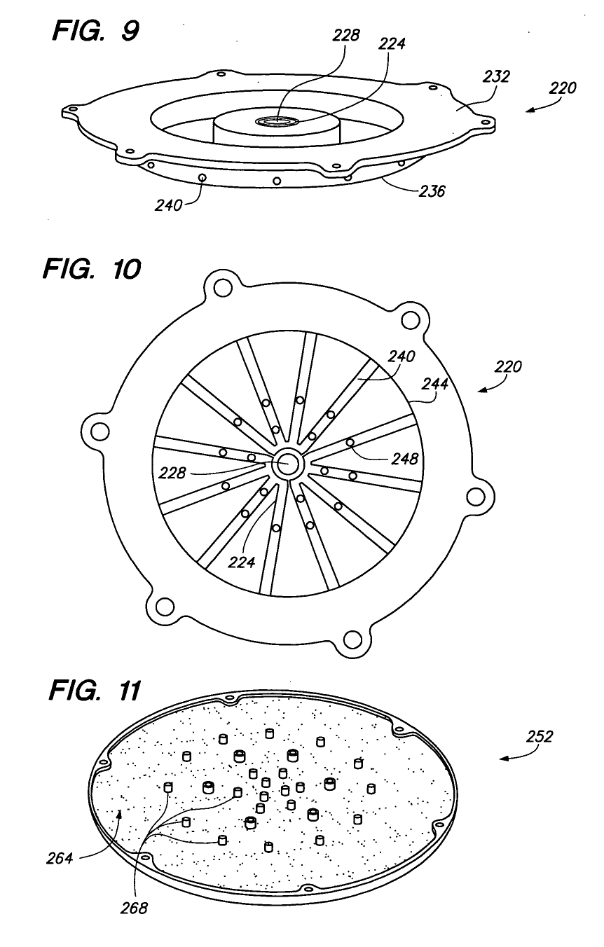

This embodiment of the dual channel gas distributor 108 comprises a remotely energized gas channel 238 having a first inlet 110a to receive the remotely energized first process gas and a plurality of first outlets 354a to release the remotely energized first process gas into the process zone 100. For example, in one version, the first inlet 110a to the remotely energized gas channel 238 can be formed in an embodiment of the cover plate 220, illustrated in FIG. 9, which receives the energized first process gas and the non-energized second process gases from the gas manifold 216. In this version, the first gas conduit 224 has the first inlet 110a which receives the remotely energized first process gas. The first gas conduit 224 is typically an annular passage and connects to a plurality of channels 240 extending radially outward to a perimeter 244 of the cover plate 220. The plurality of radial channels 240, also illustrated in the cross-sectional top view of the cover plate 220 in FIG. 10, receive the energized first process gas from the first conduit 224. The cover plate 220 further comprises a plurality of holes 248 extending from the radial channels 240 through the bottom surface 236 of the cover plate 220 to distribute energized first process gas to the first outlets 354a.

This embodiment of the dual channel gas distributor 108 also comprises a non-energized gas channel 242 comprising the second inlet 110b to receive the second non-energized process gas and a plurality of second outlets 354b to introduce the non-energized second process gas into the process zone 100. For example, in one version, the second inlet 110b to the non-energized gas channel 242 can be at the intersection of the second gas conduit 228, a central passage relative to the first gas conduit 224, with the top surface 232 of the cover plate 220. The second conduit 228 receives the non-energized second process gas and extends from the top surface 232 to the bottom surface 236 of the cover plate 220.

In this embodiment, the dual channel gas distributor 108 also comprises an embodiment of the spreader plate 252, illustrated in FIG. 11, which has the body 256 that is spaced apart from the cover plate 220 by a separation distance to form the gas spreading box 260 having the gas spreading zone 261 between the spreader plate 252 and the cover plate 220 to receive the second process gas from the second conduit 228. The spreader plate 252 has a plurality of holes 264 which form the second outlets 354b coupling the gas spreading box 260 to the process zone 100 and distributing the non-energized second process gas to the process zone 100. This embodiment of the spreader plate 252 further has a plurality of gas tubes 268 extending from the holes 248 in the bottom surface 236 of the cover plate 220 through the spreader plate 252 to distribute the energized first process gas to the process zone 100 from the radial channels 240 of the cover plate 220. The intersection of the gas tubes 268 with the bottom surface of the spreader plate 252 form the plurality of first outlets 354a. The gas tubes 268 may comprise, for example, cylindrical tubes, and are aligned with and hermetically coupled to the holes 248 in the bottom surface 236 of the gas box 220.

In one version, the plurality of first outlets 354a each have a size d₁ and the plurality of second outlets 354b each have a size d₂. The ratio of the size of the first outlets 354a to the size of the second outlets 354b, d₁:d₂, in this version is selected to be sufficiently high to reduce the pressure drop experienced by the energized first process gas as it travels through the first gas flow pathway 112a of the gas distributor 108 from the remote plasma system 156, and sufficiently low to allow for effective and uniform mixing of the energized first process gas with the non-energized second process gas in the process zone 100. Reducing the pressure drop experienced by the first process gas as it travels along the first gas flow pathway 112a of the gas distributor 108 from the remote plasma system 156 is important to optimize the ability of the remote plasma system 156 to generate and deliver an energized process gas because it reduces the recombination of species of the energized process gas as they travel along the first gas flow pathway 112a. Effective and uniform mixing of the first and second process gases is important to prevent gas phase nucleation in the process zone 100 and uneven deposition of layers on the substrate 32. In one version, the ratio d₁:d₂ is selected to be from about 5:1 to about 20:1. For example, in one version, the first outlets 354a can be circular and sized to have a diameter of from about 2.5 mm to about 10 mm, and the second outlets 354b can also be circular and have a size of from about 0.3 mm to about 2.5 mm. In some version, the size of each individual outlet within the plurality of first outlets 354a or the plurality of second outlets 354b may vary. For example, the size of each individual first outlet 354a or each individual second outlet 354b may vary radially from the center outward to the perimeter of the spreader plate 252.

In one version, the dual channel gas distributor 108 shown in FIG. 8 may also comprise a plurality of third outlets 354c to release the remotely energized process gas into the process zone 100. For example, the plurality of third outlets 354c can be formed at the intersection of the radial channels 240 with the perimeter 244 of the cover plate 220. In one version, the plurality of third outlets 354c each have a size d₃. For example, the radial channels 240 can have a cross-sectional size d₃ that determines the size of the third outlets 354c. The ratio of the size of the third outlets 354c to the size of the second outlets 345b, d₃:d₂, is selected to be sufficiently high to reduce the pressure drop experienced by the energized first process gas as it travels from the remote plasma system 156 through the first gas flow pathway 112a, and sufficiently low to allow for effective and uniform mixing of the energized first process gas with the non-energized second process gas in the process zone 100. In one version, the ratio d₃:d₂ is selected to have a value of from about 10:1 to about 40:1. In one version, the size of the third outlets d₃ is selected to have a value of from about 5 mm to about 20 mm.

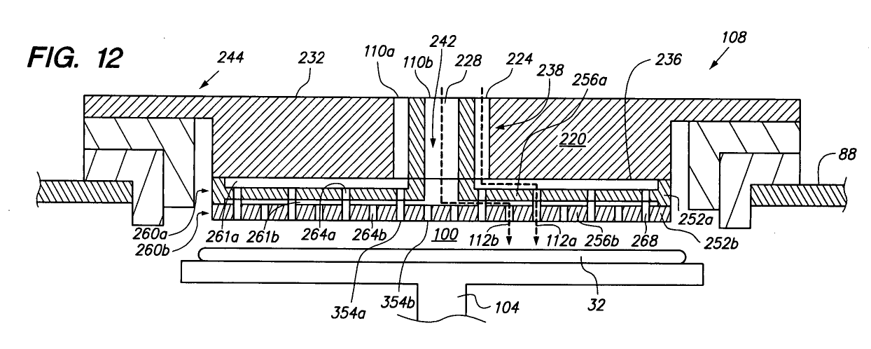

Another version of the dual channel gas distributor 108 capable of receiving and separately distributing the remotely energized first process gas and the non-energized second process gas to the process zone 100 is illustrated in the cross-sectional view of FIGS. 12. This embodiment also comprises the cover plate 220 comprising the first and second inlets 110a,b to receive the energized first and non-energized second process gases from the gas manifold 216. In this embodiment, the cover plate 220 has the first conduit 224 to receive the energized first process gas and the second conduit 228 to receive the non-energized second process gas. However, in this embodiment, the cover plate 220 does not have radial channels 240 extending from the fist conduit 224.

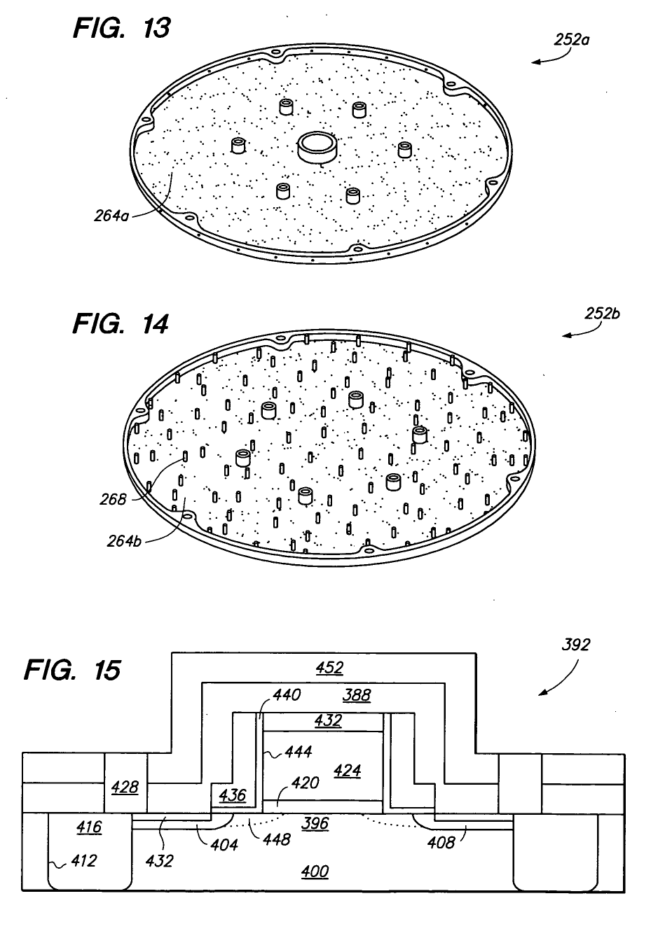

Instead, this embodiment of the dual channel gas distributor 108 comprises two spreader pates 252 to form two gas spreading boxes 260 below the cover plate 220. An upper or first spreader plate 252a, illustrated in FIG. 13, has a body 256a that is spaced apart from the cover plate 220 by a first separation distance to form a first gas spreading box 260a having a first gas spreading zone 261a to receive the remotely energized first process gas from the first conduit 224. The first spreader plate 252a also has a plurality of holes 264a extending from the first gas spreading box through the first spreader pate 252a. A lower or second spreader plate 252b, illustrated in FIG. 14, has a body 256b that is spaced apart from the first spreader plate 252a by a second separation distance to form a second gas spreading box 260b having a second gas spreading zone 261b to receive the non-energized second process gas from the second conduit 228.

The second spreader plate 252b has a plurality of holes 264b extending from the second gas spreading box 260b through the second spreader plate 252b to distribute the second process gas to the process zone 100. The intersection of the holes 264b with the bottom surface of the second spreader plate 252b form the second outlets 354b of the gas distributor 108. The second spreader plate 252b also has a plurality of gas tubes 268 extending from the holes 264a in the first spreader pate 252a through the second spreader plate 252b to distribute the energized first process gas to the process zone 100 from the first spreading box 260a. The intersection of the gas tubes 268 with the bottom surface of the second spreader plate 252b form the first outlets 354a of the dual channel gas distributor 108. As discussed above, the first and second outlets 354a,b may comprise circular openings and may be sized to provide an advantageous characteristics to the introduction of the energized first process gas and the non-energized second process gas to the process zone 100. Additionally, the number of outlets in the plurality of first and second outlets 354a,b can be selected to optimize the relative spatial distributions of the energized first process gas and the non-energized second process gas in the process zone 100. For example, in one version, the plurality of first outlets 354a comprises from about 30 to about 200 first outlets 354a and the plurality of second outlets 354b comprises from about 300 to about 2000 second outlets 354b.

The embodiments of the dual channel gas distributor 108 shown in FIGS. 8 and 12 are absent the faceplate 312. The absence of the faceplate 312 is advantageous for the embodiments of the gas distributor 108 shown in FIGS. 8 and 12 to enhance the delivery of energized plasma species to the process zone 100. For example, in the embodiments shown in FIGS. 8 and 12, first and second gas flow pathways 112a,b, as well as the outlets 354 of the gas distributor 108 are optimized to preserve the energized plasma species traveling from the remote plasma system 156 to the process zone 100 as well as to optimize the mixing of the first and second process gases in the process zone 100. However, in some versions, the embodiments of the dual channel gas distributor 108 shown in FIGS. 8 and 12 may also have the faceplate 312 positioned as illustrated in FIG. 3. Additionally, the embodiments of the gas distributor 108 shown in FIGS. 8 and 12 are absent the plasma isolator 276. However, in some versions, the plasma isolator 276 can be used in the embodiments of the gas distributor 108 shown in FIGS. 8 and 12. The plasma isolator 276 can be placed in the second conduit 228, as illustrated in FIG. 3.

Another version of the method to deposit the layer on the substrate 32 is suitable use with the embodiment of the dual channel gas distributor 108 illustrated in FIGS. 8 and 12. In this version of the method, the first process gas is energized remotely from the process zone 100 before it is introduced into the process zone 100 by the gas distributor 108. For example, the first process gas can be energized in the remote plasma zone 160 of the remote plasma chamber 180 of the remote plasma system 156. The remotely energized first process gas is introduced into the process zone 100 through the first gas pathway 112a of the dual channel gas distributor 108. Simultaneously with introducing the remotely energized first process gas to the process zone 100, the second non-energized process gas is separately introduced into the process zone 100 through a second gas flow pathway 112b of the dual channel gas distributor 108. In this version of the method to deposit the layer on the substrate 32, the first process gas can be remotely energized using any of the versions of the remote plasma system 156 shown in FIGS. 2a-c. For example, the first process gas can be energized by coupling microwave energy to the first process gas, as well as by coupling RF energy to the first process gas.

The method to deposit the layer on the substrate 32 can be used to deposit a silicon nitride layer 388 as part of the fabrication of a MOSFET 392 which is illustrated in the simplified cross-sectional view of FIG. 15. The method is optimized to deposit a silicon nitride layer 388 which has a relatively high internal tensile stress. Internal tensile stress in the silicon nitride layer 388 produces a tensile strain in a channel region 396 of the transistor 392. The induced strain improves carrier mobility in the channel region 396 which improves important performance measures, for example the saturation current, of the transistor 392. The silicon nitride layer 388 may have other uses and benefits within the MOSFET 392, such as for example, functioning as an etch stop layer to protect other components of the transistor 392 during etching processes performed to form the MOSFET 392. Additionally, although the high tensile stress silicon nitride layer 388 is shown as part of a MOSFET 392, the high tensile stress silicon nitride layer 388 can be useful in other structures formed on a substrate, such as, for example, other types of transistors such as bipolar junction transistors, capacitors, sensors, and actuators.

The transistor 392 illustrated in FIG. 15 has a semiconductor substrate 400 comprising, for example, silicon. The substrate 400 may also comprise other semiconductor materials such as germanium, silicon germanium, gallium arsenide, or combinations thereof. Additionally, in some instances the substrate 400 may comprise an insulator. In the deposition of the silicon nitride layer 388, the substrate 32 handled by the substrate transport 106 and processed by the substrate processing chamber 80 may be the transistor substrate 400 of the transistor 392 shown in FIG. 15, or in some versions, it may comprise a separate substrate upon which the transistor substrate 400 is formed.

The transistor 392 illustrated in FIG. 15 is an negative channel, or n-channel, MOSFET (NMOS) having source and drain regions 404, 408 that are formed by doping the substrate 400 with a Group VA element to form an n-type semiconductor. In the NMOS transistor, the substrate 400 outside of the source and drain regions 404, 408 is typically doped with a Group IIIA element to form a p-type semiconductor. In another version, however, the MOSFET transistor 392 may comprise a positive channel, or p-channel MOSFET (PMOS) having source and drain regions that are formed by doping the substrate with a Group IIIA element to form a p-type semiconductor. In a PMOS transistor, the transistor 392 may comprise a substrate 400 comprising an n-type semiconductor or may have a well region (not shown) comprising a n-type semiconductor formed on an substrate 400 comprising a p-type semiconductor.

In the version shown, the transistor 392 comprises a trench 412 to provide isolation between transistors 392 or groups of transistors 392 on the substrate 400, a technique known as shallow trench isolation. The trench 412 is typically formed prior to the source and drain regions 404, 408 by an etch process. A trench side wall liner layer (not shown) may be formed in the trench 412 by, for example, a rapid thermal oxidation in an oxide/oxinitride atmosphere, which may also round sharp corners on the trench 412 (and elsewhere). In one version, the trench 412 may be filled with material 416 having a tensile stress, which can also be used to provide a tensile stress to the channel region 396. The deposition of the trench material 416 which may include the use of a High Aspect Ratio Process (HARP), which may include using an O₃/tetraethoxy silane (TEOS) based sub-atmospheric chemical vapor deposition (SACVD) process. Excess trench material 416 may be removed by, for example, chemical mechanical polishing.

The transistor comprises a gate oxide layer 420 and a gate electrode 424 on top of the channel region 396 between the source and drain regions 404, 408. In the version shown, the transistor 392 also comprises silicide layers 432 on top of the source and drain regions 404, 408 as well as the gate electrode 424. The silicide layers 432 are highly conductive compared to the underlying source and drain regions 404, 408 and gate electrode 424, and facilitate the transfer of electric signals to and from the transistor 392 through metal contacts 428. Depending on the materials and formation processes used, the silicide layers 432 may also comprise a tensile stress and produce tensile strain in the channel region 396. The transistor shown also comprises spacers 436 and oxide-pad layers 440 which may be located on opposite sidewalls of the gate electrode 424 to keep the suicide layers 432 separated during a silicidation process to form the suicide layers 432. During silicidation, a continuous metal layer (not shown) is deposited over the oxide-containing source and drain regions 404, 408 and gate electrode 424, as well as the nitride containing spacers 436. The metal reacts with the underlying silicon in the source and drain regions 404, 408 and gate electrode 424 to form metal-silicon alloy silicide layers, but are less reactive with the nitride materials in spacers 436. Thus, the spacers 436 allow the overlying, unreacted metal to be etched away while not affecting the metal alloy in silicide layers 432.

The length of the channel region 396 is shorter than the length of the gate oxide layer 420. The length of the channel region 396 measured between the edges of the source region 404 and the drain region 408 may be about 90 nm or less, for example, from about 90 nm to about 10 nm. As the length of channel region 396 gets smaller, implants 448, also known as halos, may be counterdoped into the channel region 396 to prevent charge carriers from uncontrollably hopping from the source region 404 to the drain region 408 and vice versa.

In the version shown in FIG. 15, the silicon nitride layer 388 is formed above the silicide layers 432. The silicon nitride layer 388 typically acts as a contact-etch stop layer as well as a providing strain to the channel region 396. The silicon nitride layer 388 is capable of being deposited to have a stress values ranging from compressive to tensile stresses. The selection of the stress in the silicon nitride layer 388 selects the type of strain provided to the channel region 396 of the transistor 392. In a preferred embodiment, the silicon nitride layer 388 is deposited to have a relatively high tensile stress, which provides a relatively high tensile strain to the channel region 396.

Following the formation of the silicon nitride layer 388, a dielectric layer 452, also referred to as a pre-metal dielectric layer, may be deposited on the silicon nitride layer 388. The dielectric layer 452 may be, for example, borophosphosilicate glass, phosphosilicate glass, borosilicate glass, and phosphosilicate glass, among other materials. The dielectric layer 452 may be formed using HARP that includes O₃/TEOS in conjunction with SACVD. The dielectric layer 452 may also comprise a tensile stress which produces a tensile strain in the channel region 396.

In the method to deposit the silicon nitride layer 388, the first process gas comprises a nitrogen-containing gas such as, for example, nitrogen, ammonia, or a combination thereof. The second process gas comprises a silicon-containing gas such as, for example, silane, disilane, trimethylsilane (TMS), tetrakis(dimethylamido)silicon (TDMAS), bis(tertiary-butylamine)silane (BTBAS), dichlorosilane (DCS), or a combination thereof. In one version, the energized first process gas is introduced into the process zone 100 at a flow rate of, for example, from about 10 sccm to about 1000 sccrm, and the second process gas is introduced into the process zone 100 at a flow rate of, for example, from about 10 sccm to about 500 sccm. These flow rates are advantageous to help sustain the plasma in the localized plasma zone 219 of the dual channel gas distributor 108 or the remote plasma zone 160 of the remote plasma system 156. The pressure in the process zone 100 is maintained to be from about 100 mTorr to about 10 Torr. This pressure range is advantageous because it is sufficiently high to create a relatively high deposition rate and sufficiently low to sustain the plasma in the localized plasma zone 219 or remote plasma zone 160.

Activation of the CVD reaction by generating a plasma from the first process gas is advantageous because it provides for a relatively lower temperature process in comparison to a thermally activated CVD process. A lower temperature silicon nitride deposition process is advantageous because it creates a silicon nitride layer 388 without the need to expose other layers on the substrate to potentially damaging higher temperatures. In one version, the temperature of the substrate 36 in the process zone 100 is maintained at from about 100° C. to about 500° C. This temperature range is advantageous because typically the silicon nitride layer 388 is formed after the silicide layer 432. For example, the silicide layer 432 may comprise NiSi, which typically may be harmed by temperatures above 500° C. due to agglomeration of Ni within the silicide layer 432 at these higher temperatures which may, for example, undesirably increase the resistivity of the silicide layer 432. The substrate processing chamber 80 may comprise a temperature sensor (not shown) such as a thermocouple or an interferometer to detect the temperature of surfaces, such as component surfaces or substrate surfaces, within the substrate processing chamber 80. The temperature sensor is capable of relaying its data to the chamber controller 196 which can then use the temperature data to control the temperature of the processing chamber 80, for example by controlling the resistive heating element in the substrate support 104.

Generating plasma from the first process gas remotely from the process zone, either in the remote plasma chamber 180 of the remote plasma system 156, or the localized plasma zone 204 of the dual channel gas distributor 108, provides for the formation of the silicon nitride layer 20 having improved properties. For example, generating the plasma remotely from the process zone 100 provides for the formation of the silicon nitride layer 388 having a relatively higher internal tensile stress. The remotely generated plasma has energetic plasma species that have relatively less energy and are also less directionally focused than energetic particles and gaseous species in a plasma formed directly in the process zone 100. Highly energetic and directional plasma species impact the silicon nitride layer 388 during its formation and undesirably compress the silicon nitride layer 388, creating more compressive stress in the silicon nitride layer 388. In contrast, the silicon nitride layer 388 formed by remotely generating the plasma from the first process gas is exposed to less bombardment by energetic and directionally focused plasma species during its formation, due to the presence of the relatively less energetic and directionally focused plasma species, which reduces the compressive forces experienced by the silicon nitride layer 388 during its formation. Thus, the silicon nitride layer 388 formed by remotely energizing the first process gas is capable of having higher intrinsic tensile stress, which produces relatively higher tensile strain in the channel region 396, thereby improving carrier mobility in the channel 396 and thus the performance of the transistor 392.

In one version of the method to form the silicon nitride layer 388, energy may also be coupled directly into the process zone 100 to further energize the process gases, which may increase the speed at which the process can be conducted without excessively affecting the internal stress of the deposited layer 388. Because the first process gas is energized prior to entering the process zone 100, the energy coupled directly into the process zone 100 may be a relatively small amount in comparison to the energy required to create and maintain the plasma in the process zone 100. For example, the amount of energy coupled into the process zone 100 may only need to be sufficient to maintain or increase the energy of energetic plasma species. Thus, energy can be coupled into the process zone 100 in a manner that does not excessively influence the tendency or the force with which energetic particles in the process zone 100 impact the silicon nitride layer 388 as it is being formed.

In one version, energy such as, for example, RF or microwave energy, can be coupled into the process zone 100 using a chamber gas energizer (not shown). In one version, the chamber gas energizer may comprise chamber electrodes that are powered by a power supply to capacitively couple energy to the process gasses in the process zone 100. The chamber electrodes may include an electrode that is in the enclosure wall 84, such as the sidewall 92 or ceiling 88 of the chamber 80, which may be used in conjunction with another chamber electrode, such as an electrode below the substrate 32 in the support pedestal 104. In another version, the chamber gas energizer may comprise an antenna comprising one or more inductor coils about the chamber 80 used to inductively couple energy into the process gases in the process zone 100.

Although exemplary embodiments of the present invention are shown and described, those of ordinary skill in the art may devise other embodiments which incorporate the present invention, and which are also within the scope of the present invention. For example, the deposition method and embodiments of the dual channel gas distributor 108 described herein may also be useful in other aspects, such as for example, in depositing dielectric layers in an atomic layer deposition (ALD) process. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements described herein to illustrate the invention.

What is claimed is:

1. A dual channel gas distributor to simultaneously distribute plasma species of a first process gas and a non-plasma second process gas into a process zone of a substrate processing chamber, the gas distributor comprising:
(a) a localized plasma box comprising:
(i) a first inlet to receive a first process gas, and
(ii) opposing top and bottom plates that are capable of being electrically biased relative to one another to define a localized plasma zone in which a plasma of the first process gas can be formed, the top plate having a plurality of spaced apart gas spreading holes to spread the first process gas across the localized plasma zone, and the bottom plate comprising a plurality of first outlets to distribute plasma species of the plasma of the first process gas into the process zone; and
(b) a plasma isolated gas feed comprising:
(i) a second inlet to receive a second process gas,
(ii) a plurality of second outlets to pass the second process gas into the process zone, and a plasma isolator between the second inlet and second outlets, whereby the plasma isolator prevents formation of a plasma of the second process gas in the plasma isolated gas feed.

2. A dual channel gas distributor according to claim 1 wherein the localized plasma box comprises a first gas conduit that originates at the first inlet and terminates at a gas spreading box above the top plate.

3. A dual channel gas distributor according to claim 2 wherein the plasma isolated gas feed comprises a second gas conduit that originates at the second inlet and is a centrally located passage, and wherein the first gas conduit comprises an annular passage that is concentric about the second gas conduit.

4. A dual channel gas distributor according to claim 3 wherein the bottom plate is a faceplate facing the substrate, and wherein the faceplate comprises an interlinked network of channels that feed the second outlets.

5. A dual channel gas distributor according to claim 4 wherein the faceplate comprises an array of vertical channels extending therethrough to form the first outlets.

6. A dual channel gas distributor according to claim 1 wherein first and second outlets are interspersed with one another and substantially on the same plane.

7. A dual channel gas distributor according to claim 1 wherein the first outlets have a size d₁, the second outlets have a size d₂, and d1 and d2 have values of from about 0.1 mm to about 3 mm.

8. A dual channel gas distributor according to claim 1 wherein the plasma isolator comprises a cylindrical body having a plurality of holes sized sufficiently small to prevent the passage of a plasma therethrough.

9. A dual channel gas distributor according to claim 8 wherein the holes of the plasma isolator have a diameter of from about 2 mm to about 4 mm.

10. A dual channel gas distributor according to claim 1 wherein the localized plasma box further comprises an electrical isolator to electrically isolate the top and bottom plates from one another or from the chamber.

11. A substrate processing chamber comprising:
(1) enclosure walls to define a process zone;
(2) a gas supply system to supply the first and second process gases;
(3) a dual channel gas distributor according to claim 1;
(4) a substrate support; and
(5) a gas exhaust port to exhaust gas from the process zone.

12. A method of depositing a layer on a substrate in a processing chamber having a localized plasma zone directly above a process zone, the method comprising:
(a) placing the substrate in the process zone;
(b) forming a localized plasma and distributing the plasma species of the plasma into the process zone thorough a first gas pathway by:
(i) introducing a first process gas into the localized plasma zone,
(ii) forming a plasma from the first process gas in the localized plasma zone by maintaining an electric field across the localized plasma zone, and
(iii) distributing the plasma species of the plasma of the first process gas across the process zone;
(c) simultaneously with (b), separately introducing a non-energized second process gas into the process zone through a second gas pathway while suppressing formation of a plasma of the second process gas in the second gas pathway; and
(d) exhausting gas from the process zone, whereby a layer is deposited on the substrate.

13. A method according to claim 12 wherein the processing chamber comprises a pair of parallel electrodes that face one another to define a localized plasma zone that is located directly above the process zone, and wherein step (b) (ii) comprises coupling energy to the first process gas by electrically biasing the electrodes relative to one another.

14. A method according to claim 12 comprising applying a voltage to an electrode at a power level of about 30 W to about 1000 W, while electrically grounding the other electrode.

15. A method according to claim 12 wherein the first process gas comprises a nitrogen-containing gas, the non-energized second process gas comprises a silicon-containing gas and whereby silicon nitride is deposited on the substrate.

16. A method according to claim 15 comprising introducing the plasma species of the first process gas into the process zone at a flow rate of from about 10 sccm to about 1000 sccm and introducing the non-energized second process gas into the process zone at a flow rate of from about 10 sccm to about 500 sccm.

17. A method according to claim 15 wherein the nitrogen-containing gas comprises nitrogen, ammonia, or a combination thereof; and the silicon-containing gas comprises silane, disilane, trimethylsilane (TMS), tetrakis(dimethylamido)silicon (TDMAS), bis(tertiary-butylamine)silane (BTBAS), dichlorosilane (DCS), or a combination thereof.

18. A method according to claim 14 comprising maintaining a pressure in the process zone of from about 100 mTorr to about 10 Torr.

19. A method according to claim 14 comprising maintaining the substrate at a temperature of from about 100° C. to about 500° C.

20. A method of depositing a layer on a substrate in a substrate processing chamber, the substrate processing chamber comprising a process zone and a gas distributor to distribute first and second process gases to the process zone, the gas distributor comprising a localized plasma zone between a first and second electrode, the method comprising:
(a) placing the substrate in the process zone;
(b) introducing the first process gas to the localized plasma zone through the first electrode, applying a voltage between the first and second electrodes to couple energy to the first process gas, and introducing the energized first process gas to the process zone through a first gas pathway;
(c) separately introducing a second process gas to the process zone through a second gas pathway; and
(d) exhausting gas from the process zone, whereby a layer is deposited on the substrate.

21. A method according to claim 19 wherein the first and second gas pathways are both through the second electrode.

22. A method according to claim 19 wherein the first gas pathway terminates in a plurality of first outlets, and the second gas pathway terminates in a plurality of second outlets, and wherein the method comprises maintaining the first and second outlets spaced apart and adjacent to one another.

23. A method according to claim 19 wherein the layer comprises silicon nitride, the first process gas comprises a nitrogen-containing gas, and the second process gas comprises a silicon-containing gas.

24. A method of cleaning a substrate processing chamber, the substrate processing chamber comprising a process zone and a gas distributor having a localized plasma zone between a first and second electrode, the method comprising:
(a) introducing a first cleaning gas to the localized plasma zone through the first electrode, applying a voltage between the first and second electrodes to couple energy to the cleaning gas, and introducing the energized cleaning gas to the process zone through the second electrode; and
(b) exhausting the cleaning gas from the process zone.

25. A method of cleaning a substrate processing chamber comprising:
(c) introducing a second cleaning gas to the process zone.

26. A method of cleaning a substrate processing chamber according to claim 24 wherein the first cleaning gas comprises a fluorine-containing gas.

27. A method of cleaning a substrate processing chamber according to claim 26 wherein the first cleaning gas comprises argon.

28. A method of cleaning a substrate processing chamber according to claim 25 wherein the second cleaning gas comprises NF₃.

29. A dual channel gas distributor to simultaneously distribute into a processing chamber a first process gas remotely energized in a remote gas energizing chamber that is distal from the processing chamber and a non-energized second process gas, the gas distributor comprising:
(a) a remotely energized gas channel comprising a first inlet to receive the remotely energized first process gas and a plurality of first outlets to release the remotely energized first process gas into the processing chamber; and
(b) a non-energized gas channel comprising a second inlet to receive a second non-energized process gas and a plurality of second outlets to introduce the received non-energized second process gas into the processing chamber, the second outlets being interspersed and on substantially the same plane with the first outlets.

30. A dual channel gas distributor according to claim 29 wherein the remotely energized gas channel has a first gas conduit comprising an annular passage in a cover plate, the annular passage being concentric about a second gas conduit of the non-energized gas channel, the second gas conduit comprising a centrally located passage in the cover plate.

31. A dual channel gas distributor according to claim 29 comprising a first spreader plate between the cover plate and a second spreader plate facing the substrate, the second spreader plate having the first and second outlets.

32. A dual channel gas distributor according to claim 29 wherein each first outlet has a size d₁, each second outlet has a size d₂, and the ratio of d₁:d₂ has a value of from about 5:1 to about 20:1.

33. A dual channel gas distributor according to claim 30 wherein the cover plate comprises plurality of radial channels extending outward from the first gas conduit to the perimeter of the cover plate and the radial channels form a plurality of third outlets at the perimeter of the cover plate to release the remotely energized process gas into the processing chamber.

34. A dual channel gas distributor according to claim 33 wherein the third outlets each comprise a size d₃, the ratio d₃:d₂ being from about 10:1 to about 40:1.

35. A substrate processing chamber comprising:
(1) enclosure walls to define a process zone about a substrate support;
(2) a remote plasma box to energize a first process gas to form a remotely energized first process gas;
(3) a dual channel gas distributor according to claim 29; and
(4) a gas exhaust port to exhaust gas from the process zone.

36. A method of depositing a layer on a substrate in a processing chamber, the method comprising:
(a) placing the substrate in the process zone;
(b) forming a remotely energized first process gas in a remotely energized gas zone;
(c) introducing the remotely energized first process gas into the process zone though a first gas pathway;
(d) simultaneously with step (c), separately introducing a non-energized second process gas into the process zone through a second gas pathway; and
(d) exhausting gas from the process zone, whereby a layer is deposited on the substrate.

37. A method according to claim 36 comprising remotely energizing the first process gas by coupling microwave energy to the first process gas.

38. A method according to claim 36 comprising remotely energizing the first process gas by inductively coupling RF energy to the first process gas.

39. A method according to claim 36 comprising introducing a first process gas comprising a nitrogen-containing gas into the remotely energized gas zone, wherein the non-energized second process gas comprises a silicon-containing gas, and whereby silicon nitride is deposited on the substrate.

40. A method according to claim 39 comprising introducing the remotely energized first process gas into the process zone at a flow rate of from about 10 sccm to about 1000 sccm and introducing the non-energized second process gas into the process zone at a flow rate of from about 10 sccm to about 500 sccm.

41. A method according to claim 39 wherein the nitrogen-containing gas comprises nitrogen, ammonia, or a combination thereof; and the silicon-containing gas comprises silane, disilane, trimethylsilane (TMS), tetrakis(dimethylamido)silicon (TDMAS), bis(tertiary-butylamine)silane (BTBAS), dichlorosilane (DCS), or a combination thereof.

42. A method according to claim 39 comprises maintaining a pressure in the process zone of from about 100 mTorr to about 10 Torr.
